(19) United States
(12) Patent Application Publication
(10) Pub. No.: US 2007/0026599 A1
(43) Pub. Date: Feb. 1, 2007

(54) Methods for fabricating a stressed MOS device

(75) Inventors: Igor Peidous, Fishkill, NY (US); Akif Sultan, Austin, TX (US); Mario M. Pelella, Mountain View, CA (US)

Correspondence Address: INGRASSIA FISHER & LORENZ, P.C., 7150 E. CAMELBACK, STE. 325, SCOTTSDALE, AZ, 85251, US

(73) Assignee: ADVANCED MICRO DEVICES, INC.

(21) Appl. No.: 11/191,684

(22) Filed: Jul. 27, 2005

(51) Int. Cl. H01L 21/8238; H01L 29/94

(52) U.S. Cl. 438/199; 257/369; 257/E21.182

(57) ABSTRACT

Methods are provided for fabricating a stressed MOS device. The method comprises the steps of forming a plurality of parallel MOS transistors in and on a semiconductor substrate. The parallel MOS transistors having a common source region, a common drain region, and a common gate electrode. A first trench is etched into the substrate in the common source region and a second trench is etched into the substrate in the common drain region. A stress inducing semiconductor material that has a crystal lattice mismatched with the semiconductor substrate is selectively grown in the first and second trenches. The growth of the stress inducing material creates both compressive longitudinal and tensile transverse stresses in the MOS device channel that enhance the drive current of P-channel MOS transistors. The decrease in drive current of N-channel MOS transistors caused by the compressive stress component is offset by the tensile stress component.

### TECHNICAL FIELD OF THE INVENTION

The present invention generally relates to methods for fabricating semiconductor devices, and more particularly relates to methods for fabricating stressed MOS devices.

### BACKGROUND OF THE INVENTION

The majority of present day integrated circuits (ICs) are implemented by using a plurality of interconnected field effect transistors (FETs), also called metal oxide semiconductor field effect transistors (MOSFETs), or simply MOS transistors. An MOS transistor includes a gate electrode as a control electrode and spaced apart source and drain electrodes between which a current can flow. A control voltage applied to the gate electrode controls the flow of current through a channel between the source and drain electrodes.

MOS transistors, in contrast to bipolar transistor, are majority carrier devices. The gain of an MOS transistor, usually defined by the transconductance (gₘ), is proportional to the mobility of the majority carrier in the transistor channel. The current carrying capability of an MOS transistor is proportional to the mobility times the width of the channel divided by the length of the channel (gₘ W/l). MOS transistors are usually fabricated on silicon substrates with the crystallographic surface orientation (100), which is conventional for silicon technology. For this and many other orientations, the mobility of holes, the majority carrier in a P-channel MOS transistor, can be increased by applying a compressive longitudinal stress to the channel. Such a compressive longitudinal stress, however, decreases the mobility of electrons, the majority carriers in N-channel MOS transistors. A compressive longitudinal stress can be applied to the channel of an MOS transistor by embedding an expanding material such as pseudomorphic SiGe in the silicon substrate at the ends of the transistor channel [For example, see IEEE Electron Device Letters v. 25, No 4, p. 191, 2004]. A SiGe crystal has greater lattice constant than the lattice constant of a Si crystal, and consequently the presence of embedded SiGe causes a deformation of the Si matrix. Unfortunately, present techniques for increasing carrier mobility by embedding an expanding material cannot be applied in the same way to both P-channel and N-channel MOS transistors because the compressive longitudinal stress that improves hole mobility is detrimental to electron mobility. Also, the present techniques exploit only phenomenon of carrier mobility enhancement by the longitudinal stress, neglecting the transverse stress that also influences the mobility.

Accordingly, it is desirable to provide methods for fabricating stressed MOS devices that utilize both longitudinal and transverse stresses. In addition, it is desirable to provide methods for fabricating stressed MOS devices that improve the carrier mobility of both N-channel and P-channel devices. Furthermore, other desirable features and characteristics of the present invention will become apparent from the subsequent detailed description and the appended claims, taken in conjunction with the accompanying drawings and the foregoing technical field and background.

### BRIEF SUMMARY OF THE INVENTION

Methods are provided for fabricating a stressed MOS device in and on a semiconductor substrate. The method comprises the steps of forming a plurality of parallel MOS transistors in and on the semiconductor substrate, the plurality of parallel MOS transistors having combined source region, combined drain region, and a common gate electrode. A first recess is etched into the semiconductor substrate in the combined source region and a second recess is etched into the semiconductor substrate in the combined drain region. A stress inducing semiconductor material having a lattice constant greater than the lattice constant of the semiconductor substrate is selectively grown in the first trench and the second trench.

### BRIEF DESCRIPTION OF THE DRAWINGS

The present invention will hereinafter be described in conjunction with the following drawing figures, wherein like numerals denote like elements, and wherein

FIGS. 1, and 4-8 illustrate, in cross section, a stressed MOS device and methods for its fabrication in accordance with various embodiments of the invention; and

FIGS. 2 and 3 illustrate schematically, in plan view, a portion of a stressed MOS device at a stage of its fabrication.

### DETAILED DESCRIPTION OF THE INVENTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

In a typical complementary MOS (CMOS) integrated circuits, high performance P-channel MOS transistors N-channel MOS transistors each have a relatively wide channel width to provide sufficient drive current. The channel width of such transistors is on the order of 1 μm while the channel length and the depth of the source and drain regions are less than about 0.1 μm. If stress inducing material having a thickness of the same order of magnitude as the source and drain regions is embedded at the ends of the channel, such stress inducing materials can apply a longitudinal stress along the channel, but are relatively ineffective in applying a transverse stress to the channel. Notable transverse stresses are induced only at the edges of the channel, and such stresses propagate within the channel to a distance only of the same order of magnitude as the thickness of the stress inducing material. As a result, high transverse stresses are induced only in a small portion of the channel and have little effect on device performance. In accordance with an embodiment of the invention, this problem is overcome by replacing wide channel MOS transistors with a plurality of narrow channel MOS transistors coupled in parallel. A narrow channel transistor having a stress inducing material embedded at the ends of the channel experiences both a compressive longitudinal stress and a tensile transverse stress across the whole channel region. The compressive longitudinal stress increases the hole mobility and decreases the electron mobility in the channel while the tensile transverse stress increases both the hole mobility and the electron mobility in the channel.

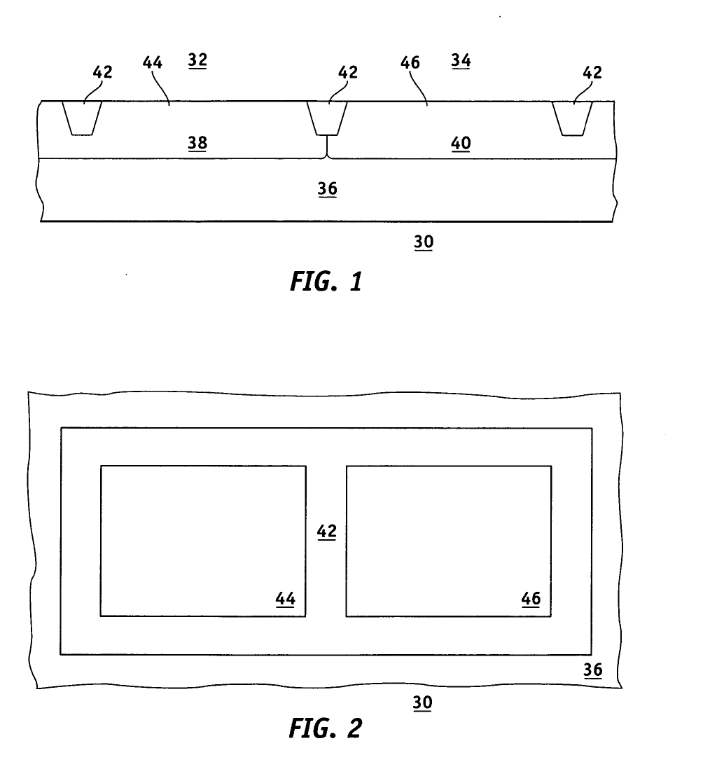

FIGS. 1-8 illustrate a stressed MOS device 30 and method steps for manufacturing such an MOS device in accordance with various embodiments of the invention. In this illustrative embodiment the only portion of stressed MOS device 30 that is illustrated is a single P-channel MOS transistor 32 and a single N-channel MOS transistor 34. An integrated circuit formed from stressed MOS devices such as device 30 can include a large number of such transistors. Although complementary MOS transistors are illustrated, the invention is also applicable to devices that include only P-channel MOS transistors.

Various steps in the manufacture of MOS transistors are well known and so, in the interest of brevity, many conventional steps will only be mentioned briefly herein or will be omitted entirely without providing the well known process details. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

As illustrated in FIG. 1, the fabrication of a stressed MOS device 30 in accordance with an embodiment of the invention begins with providing a semiconductor substrate 36. The semiconductor substrate is preferably a monocrystalline silicon substrate wherein the term “silicon substrate” is used herein to encompass the relatively pure silicon materials typically used in the semiconductor industry. Silicon substrate 36 may be a bulk silicon wafer or a thin layer of silicon on an insulating layer (commonly know as silicon-on-insulator or SOI) that, in turn, is supported by a silicon carrier wafer, but is here illustrated, without limitation, as a bulk silicon wafer. Preferably the silicon wafer has either a (100) or (110) orientation. One portion 38 of the silicon wafer is doped with N-type impurity dopants (an N-well) and another portion 40 is doped with P-type impurity dopants (a P-well). The N-well and P-well can be doped to the appropriate conductivity, for example, by ion implantation. Shallow trench isolation (STI) 42 is formed to electrically isolate between the N-well and P-well and to isolate around individual devices that must be electrically isolated. The STI defines an active area 44 for the formation of P-channel MOS transistor 32 and an active area 46 for the formation of N-channel MOS transistor 34. As is well known, there are many processes that can be used to form the STI, so the process need not be described here in detail. In general, STI includes a shallow trench that is etched into the surface of the semiconductor substrate and that is subsequently filled with an insulating material. After the trench is filled with the insulating material, the surface is usually planarized, for example by chemical mechanical planarization (CMP). The two wells and the STI are illustrated in cross section in FIG. 1 and in top view in FIG. 2.

In accordance with an embodiment of the invention P-channel transistor 32 and N-channel transistor 34 are both wide channel MOS transistors and are both implemented as a plurality of narrow channel MOS transistors coupled in parallel. As will be explained more fully below, P-channel MOS transistor 32 and N-channel MOS transistor 34 each includes a common source, a common drain, a common gate, and a plurality of parallel channels extending from the source to the drain beneath the common gate. As illustrated in FIG. 3, the plurality of parallel channels 50 of P-channel MOS transistor 32 are defined by a plurality of STI regions 52 that are formed in the surface of active area 44. As also illustrated in FIG. 3, the plurality of parallel channels 54 of N-channel MOS transistor 34 are defined by a plurality of STI regions 56 that are formed in the surface of active area 46. The STI regions can be formed at the same time as STI region 42 or can be formed separately. FIG. 3, like FIG. 2, illustrates stressed MOS device 30 in top view. The plurality of parallel channels preferably each have a width of about 0.1 μm. Although only three parallel channels are shown for each of the transistors, the total number of parallel channels for each of P-channel MOS transistor 32 and for N-channel transistor 34 are selected to provide the equivalent channel width of the single wide channel transistor each is designed to replace. Preferably the channels are oriented along the <110> crystalline direction.

A layer of gate insulator 60 is formed on the surface of silicon substrate 36, including on the surface of active areas 44 and 46 as illustrated in FIG. 4. The gate insulator may be a thermally grown silicon dioxide layer formed by heating the silicon substrate in an oxidizing ambient, or may be a deposited insulator such as a silicon oxide, silicon nitride, a high dielectric constant insulator such as HfSiO, or the like. Deposited insulators can be deposited by chemical vapor deposition (CVD), low pressure chemical vapor deposition (LPCVD), or plasma enhanced chemical vapor deposition (PECVD). In the illustrated embodiment the layer of gate insulator is a deposited insulator that deposits equally on the STI and on the silicon substrate. The gate insulator material is typically 1-10 nanometers (nm) in thickness. In accordance with one embodiment of the invention a layer of polycrystalline silicon 62 is deposited onto the layer of gate insulator. The layer of polycrystalline silicon is preferably deposited as undoped polycrystalline silicon and is subsequently impurity doped by ion implantation. A layer 64 of hard mask material such as silicon oxide, silicon nitride, or silicon oxynitride can be deposited onto the surface of the polycrystalline silicon. The polycrystalline material can be deposited to a thickness of about 100 nm by LPCVD by the hydrogen reduction of silane. The hard mask material can be deposited to a thickness of about 50 nm, also by LPCVD.

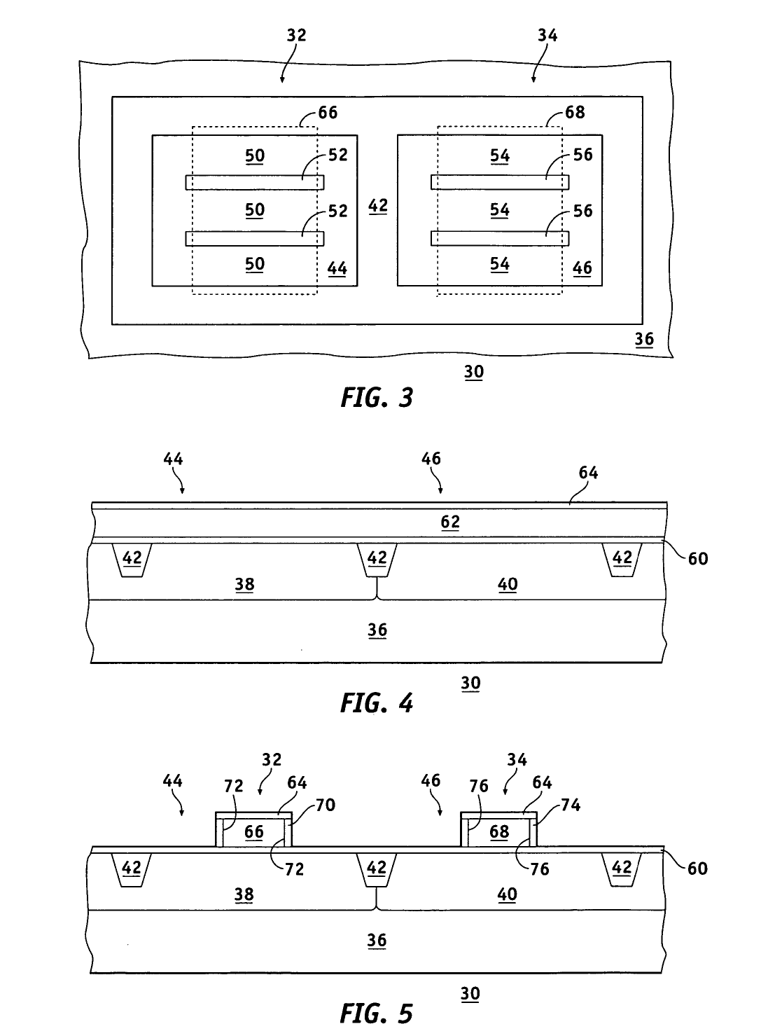

Hard mask layer 64 and underlying layer of polycrystalline silicon 62 are photolithographically patterned to form a P-channel MOS transistor gate electrode 66 overlying active area 44 and an N-channel MOS transistor gate electrode 68 overlying active area 46 as illustrated in FIG. 5. Gate electrode 66 overlies the plurality of parallel channels 50 of P-channel MOS transistor 32 and gate electrode 68 overlies the plurality of parallel channels 54 of N-channel MOS transistor 34. Gate electrodes 66 and 68 are also illustrated by dashed lines in FIG. 3. The polycrystalline silicon can be etched in the desired pattern by, for example, plasma etching in a Cl or HBr/O₂ chemistry and the hard mask can be etched, for example, by plasma etching in a CHF₃, CF₄, or SF₆ chemistry. Following the patterning of the gate electrode, in accordance with one embodiment of the invention, a thin layer 70 of silicon oxide is thermally grown on the opposing sidewalls 72 of gate electrode 66 and a thin layer 74 of silicon oxide is thermally grown on the opposing sidewalls 76 of gate electrode 68 by heating the polycrystalline silicon in an oxidizing ambient. Layers 70 and 74 can be grown to a thickness of about 2-5 nm. Gate electrodes 66 and 68 and layers 70 and 74 can be used as an ion implantation mask to form source and drain extensions (not illustrated) on either or both of the MOS transistors. The possible need for and method of forming multiple source and drain regions are well known, but are not germane to this invention and hence need not be explained herein.

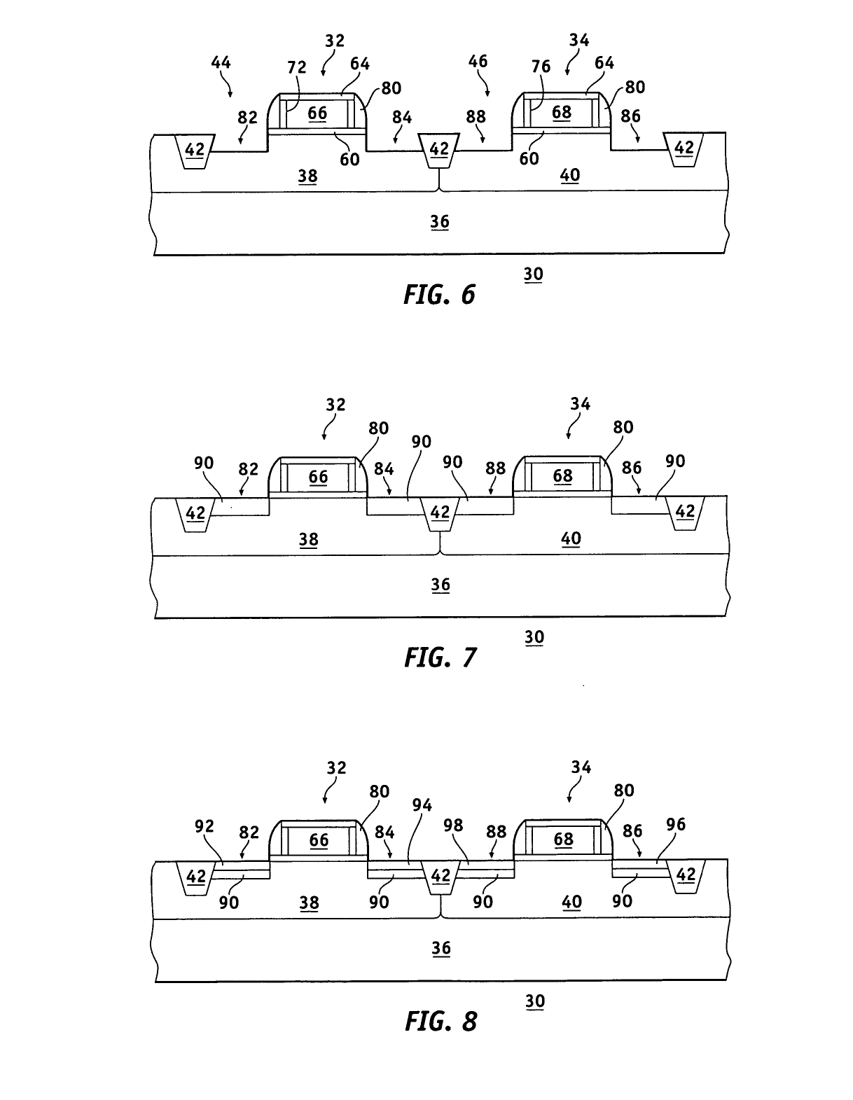

In accordance with one embodiment of the invention, as illustrated in FIG. 6, sidewall spacers 80 are formed on the opposing sidewalls 72 and 76 of gate electrodes 66 and 68, respectively. The sidewall spacers can be formed of silicon nitride, silicon oxide, or the like by depositing a layer of the spacer material over the gate electrodes and subsequently anisotropically etching the layer, for example by reactive ion etching. Sidewall spacers 80, gate electrodes 66 and 68, the hard mask on the top of the gate electrodes, and STI 42 are used as an etch mask to etch trenches 82 and 84 in the silicon substrate in spaced apart self alignment with P-channel gate electrode 66 and to etch trenches 86 and 88 in spaced apart self alignment with N-channel gate electrode 68. The trenches intersect the ends of the narrow parallel channels 50 and 54. The trenches can be etched, for example, by plasma etching using HBr/O₂ and Cl chemistry. Preferably each of the trenches has a depth that is the same order of magnitude as the width of the narrow parallel channels 50 and 54.

As illustrated in FIG. 7, the trenches are filled with a layer of stress inducing material 90. The stress inducing material can be any pseudomorphic material that can be grown on the silicon substrate with a different lattice constant than the lattice constant of silicon. The difference in lattice constant of the two juxtaposed materials creates a stress in the host material. The stress inducing material can be, for example, monocrystalline silicon germanium (SiGe) having about 10-30 atomic percent germanium. Preferably the stress inducing material is epitaxially grown by a selective growth process to a thickness that is the same order of magnitude as the width of the narrow parallel channels 50 and 54. Methods for epitaxially growing these materials on a silicon host in a selective manner are will known and need not be described herein. In the case of SiGe, for example, the SiGe has a greater lattice constant than silicon and a compressive longitudinal stress in the transistor channel. By itself, the compressive longitudinal stress increases the mobility of holes in the channel and hence improves the performance of a P-channel MOS transistor. The compressive longitudinal stress, however, decreases the mobility of electrons in the channel of an N-channel MOS transistor. By decreasing the width of the channel of both P-channel MOS transistor 32 and N-channel transistor 34, in accordance with an embodiment of the invention, a transverse tensile stress is applied to the channel of the transistors, and such a stress increases the mobility of both holes and electrons. For the P-channel MOS transistor the tensile transverse stress increases the mobility of the majority carrier holes in addition to the increased hole mobility caused by the compressive longitudinal stresses. For the N-channel MOS transistor the increase in electron mobility caused by the transverse tensile stress helps to offset the decrease in electron mobility caused by the compressive longitudinal stress. Because of the improvement in electron mobility caused by the tensile stress, which, in turn, is caused by the embedded stress inducing material, the same processing can be applied to both the P-channel transistor and to the N-channel transistor. Because the same processing can be applied to both transistors, the N-channel transistor does not have to be masked during the etching and selective growth steps and the total process is therefore made simpler, more reliable, and hence less expensive.

Source and drain regions of the MOS transistors can be partially or completely in-situ doped with conductivity determining impurities during the process of selective epitaxial growth. Otherwise, following the growth of the stress inducing material in trenches 82, 84, 86, and 88, P-type conductivity determining ions are implanted into the stress inducing material in trenches 82 and 84 to form a source region 92 and a drain region 94 of P-channel MOS transistor 32 as illustrated in FIG. 8. Similarly, N-type conductivity determining ions are implanted into the stress inducing material in trenches 86 and 88 to form a source region 96 and a drain region 98 of N-channel MOS transistor 34.

Stressed MOS device 30 can be completed by well known steps (not illustrated) such as depositing a layer of dielectric material, etching opening through the dielectric material to expose portions of the source and drain regions, and forming metallization that extends through the openings to electrically contact the source and drain regions. Further layers of interlayer dielectric material, additional layers of interconnect metallization, and the like may also be applied and patterned to achiever the proper circuit function of the integrated circuit being implemented.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

1. A method for fabricating a stressed MOS device in and on a silicon substrate comprising the steps of:
forming a gate insulator layer on the silicon substrate;
depositing a layer of gate electrode material overlying the gate insulator layer and patterning the layer of gate electrode material to form a gate electrode having opposing side surfaces;
etching a first trench and a second trench in the silicon substrate, the first trench and the second trench spaced apart and self aligned to the opposing sides surfaces of the gate electrode;
selectively growing a layer of stress inducing material in the first trench and in the second trench;
ion implanting conductivity determining impurity ions into the stress inducing material in the first trench to form a source region and into the stress inducing material in the second trench to form a drain region; and
defining a plurality of parallel channel regions in the silicon substrate extending between the source region and the drain region beneath the gate electrode.

2. The method of claim 1 wherein the step of selectively growing comprises the step of epitaxially growing a layer comprising a semiconductor material having a lattice constant greater than the lattice constant of silicon.

3. The method of claim 2 wherein the step of selectively growing comprises the step of epitaxially growing a layer of SiGe.

4. The method of claim 1 further comprising the steps of:
forming sidewall spacers on the opposing side surfaces; and
using the sidewall spacers as an etch mask for the steps of etching the first trench and the second trench.

5. The method of claim 1 wherein the step of defining a plurality of parallel channel regions comprises the step of forming a plurality of spaced apart shallow trench isolation regions extending from the source region to the drain region.

6. The method of claim 1 wherein the step of defining a plurality of parallel channel regions comprises the step of defining a plurality of parallel channel regions each having a predetermined width and wherein the step of selectively growing comprises the step of selectively growing a layer of stress inducing material having a thickness of the same order of magnitude as the predetermined width.

7. A method for fabricating a stressed MOS device in and on a silicon substrate comprising the steps of:
forming an isolation structure in the silicon substrate to define a first region and a second region;
forming a first plurality of parallel isolation structures in the silicon substrate in the first region to define a plurality of P-channels;
forming a second plurality of parallel isolation structures in the silicon substrate in the second region to define a plurality of N-channels;
forming a first gate electrode having first opposing sides overlying the plurality of P-channels and a second gate electrode having second opposing sides overlying the second plurality of N-channels;
etching first and second trenches into the silicon surface spaced apart from the first opposing sides of the first gate electrode, the first and second trenches intersecting the plurality of P-channels;
etching third and fourth trenches into the silicon surface spaced apart from the second opposing sides of the second gate electrode, the third and fourth trenches intersecting the plurality of N-channels;
selectively growing a stress inducing material in the first and second trenches and in the third and fourth trenches;
ion implanting P-type conductivity determining impurity ions into the stress inducing material in the first trench to form a P-type source region and into the stress inducing material in the second trench to form a P-type drain region; and
ion implanting N-type conductivity determining impurity ions into the stress inducing material in the third trench to form an N-type source region and into the stress inducing material in the fourth trench to form an N-type drain region.

8. The method of claim 7 wherein the step of selectively growing a stress inducing material comprises the step of epitaxially growing a SiGe layer.

9. The method of claim 7 wherein the step of selectively growing a stress inducing material comprises the step of selectively growing a layer of monocrystalline semiconductor material having a lattice constant greater than the lattice constant of silicon.

10. A method for fabricating a stressed MOS device in and on a semiconductor substrate comprising the steps of:
forming a plurality of parallel MOS transistors in and on the semiconductor substrate, the plurality of parallel MOS transistors having a common source region, a common drain region, and a common gate electrode;
etching a first trench in the semiconductor substrate in the common source region and a second trench in the common drain region; and
selectively growing a stress inducing semiconductor material lattice mismatched with the semiconductor substrate in the first trench and in the second trench.

11. The method of claim 10 wherein the step of forming a plurality of parallel MOS transistors comprises the step of forming a plurality of parallel MOS transistor each having a channel of predetermined width.

12. The method of claim 11 wherein the step of selectively growing comprises the step of selectively growing a layer of semiconductor material having a thickness of the same order of magnitude as the predetermined width.

13. The method of claim 11 wherein the step of forming a plurality of parallel MOS transistors comprises the step of forming a plurality of parallel MOS transistor each having a channel of width less than about 0.1 μm.

14. The method of claim 10 wherein the step of selectively growing comprises the step of epitaxially growing a layer comprising SiGe.

15. The method of claim 10 wherein the step of forming a plurality of parallel MOS transistors comprises the steps of:
forming a shallow trench isolation structure to define an active area; and
dividing the active area into a common source region, a common drain region, and a plurality of parallel channel regions.

16. The method of claim 10 wherein the step of forming a plurality of parallel MOS transistors comprises the steps of:
depositing a layer of polycrystalline silicon;
patterning the layer of polycrystalline silicon to form the common gate electrode, the common gate electrode having opposing sides; and
forming sidewall spacers on the opposing sides.

17. The method of claim 16 wherein the step of etching comprises the step of etching the first trench and the second trench in alignment with the sidewall spacers.
